(19) United States
(12) Patent Application Publication
(10) Pub. No.: US 2008/0258186 A1
(43) Pub. Date: Oct. 23, 2008

(54) Source and Drain Formation in Silicon on Insulator Device

(75) Inventors: Radu Surdeanu, Roosbeek (BE); Mark Van Dal, Heverlee (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/158,104

(22) PCT Filed: Dec. 12, 2006
(86) PCT No.: PCT/IB2006/054782

§ 371 Date: Jun. 26, 2008

(30) Foreign Application Priority Data
Dec. 19, 2005 (EP) 05112432.9
Dec. 12, 2006 (IB) PCT/IB2006/054782

(51) Int. Cl. H01L 29/00; H01L 21/8236

(52) U.S. Cl. 257/288; 438/278; 257/E29.001; 257/E21.631

(57) ABSTRACT

A silicon on insulator device has a silicon layer (10) over a buried insulating layer (12). A nickel layer is deposited over a gate (16), on sidewall spacers (22) on the sides of the gate (16), and in a cavity on both sides of the gate (16) in the silicon layer (10). A doped amorphous silicon layer fills the cavity. Annealing then takes place which forms polysilicon (40) over the sidewall spacers (22) and gate (16), but where the nickel is adjacent to single crystal silicon (10) a layer of NiSi (44) migrates to the surface leaving doped single crystal silicon (42) behind, forming in one step a source, drain, and source and drain contacts.

The invention relates to a method of manufacture of source and drain of a silicon on insulator device.

As transistor dimensions continue to decrease, the challenge is to ensure that transistors continue to function correctly below 100 nm gate lengths.

One approach is to provide a different transistor structure, and an example of this kind of approach is provided in Chun-Hsing Shih et al, IEEE transactions on electronic devices volume 50 page 2294 to 2297 (2003). However, such structures are difficult to manufacture.

An alternative approach is to improve various transistor properties to improve device performance. For example, in US2005/0121731 there is proposed a process to grow abrupt junctions which forms a sidewall spacer on the sidewalls of a gate, forms doped source and drain regions by selective epitaxy and implantation, and then forms silicide over the source and drain regions. Other approaches are set out in U.S. Pat. No. 6,368,949 or U.S. Pat. No. 6,777,275.

A particularly promising avenue is to use silicon on insulator (SOI) field effect transistor (FET) devices. These are FET devices formed in a thin crystalline silicon layer above an insulator, typically a buried oxide layer (BOX).

However, a problem with the manufacture of advanced complementary metal oxide semiconductor (CMOS) SOI devices is how to control the contact and junction formation to the thin silicon layer. It is desirable to achieve an abrupt junction between the source and body and between the drain and body, and also a good contact to the source and drain.

A known way to achieve a junction is to grow silicon or silicon-germanium (SiGe) epitaxially in the source and drain areas to manufacture suitable contacts. However, this approach is very complicated and requires the use of epitaxy at an inconvenient stage of the process.

A further difficulty is that it can be difficult to contact to the thin source and drains that may occur in a silicon on insulator device.

It would therefore be desirable to provide a method for forming junctions between the source and body and between the drain and body, as well as a method for contacting the source and drain.

According to the invention there is provided a method of manufacturing a semiconductor device as set out in claim 1.

The inventors have used a discovery reported in Cheng, CF et al, IEEE transactions on electronic devices, volume 50, number 6 (2003) page 1467. Cheng et al discovered that if a thin nickel layer is deposited on crystalline silicon and an amorphous silicon layer deposited on top, temperature can cause epitaxial silicon growth at a Ni silicide front which moves through the amorphous silicon. The amorphous silicon is absorbed by Ni silicide and in which the Ni Si rejects excess silicon atoms to the crystalline region behind it.

The inventors have discovered that it is possible to form a very abrupt and well positioned junction of a CMOS device that is highly activated by the method according to the invention.

The annealing step can leave Ni silicide contacts over the doped recrystalline silicon source and drain thereby forming the contacts to the recrystalline silicon in the same step as the formation of the source and drain themselves. This significantly reduces manufacturing difficulty and hence cost.

Preferably the spacer etching step does not etch the full thickness of the silicon layer to form the cavity, thereby leaving silicon layer on the sidewalls and base of the cavity.

The invention also relates to a device manufactured by the above method.

Accordingly, in another aspect there is provided a device as set out in claim 8.

The NiSi contact extending to within 10 nm of the gate, preferably within 5 nm, is achievable using this method; the inventors are not aware of other devices with a NiSi contact so close to the gate. The junction is abrupt as it is formed by the junction between the crystalline silicon layer and the regrown crystalline silicon layer and this again is a good indicator of the use of the method since the junction is more abrupt than conventionally achievable.

For a better understanding of the invention, embodiments will be described, purely by way of example, with reference to the accompanying drawings, in which:

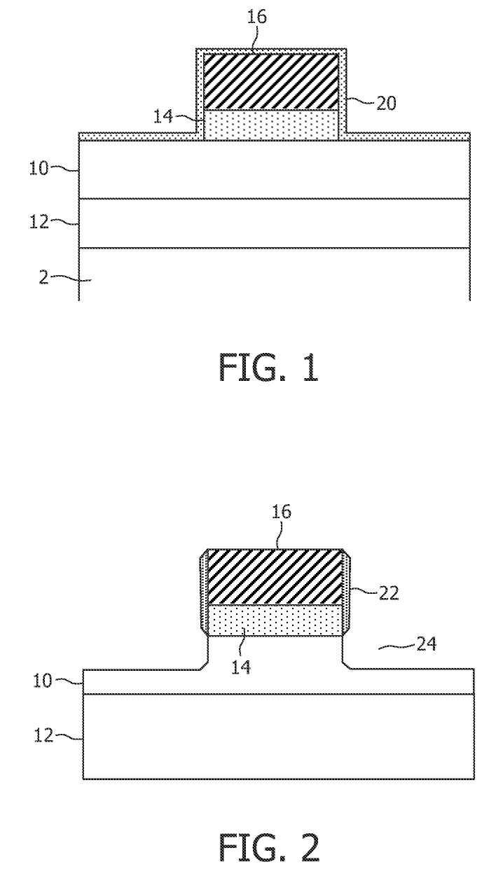

FIGS. 1 to 5 show side views of stages of a method according to an embodiment of the invention;

FIG. 6 shows a side view of an another embodiment of the invention.

Like and similar components are given the same reference numerals in the different Figures. The Figures are not to scale. In particular, the vertical direction has been exaggerated for clarity.

Referring to FIG. 1, a silicon on insulator substrate includes a silicon layer 10 above a support layer 12 in the form of a buried oxide layer 12, i.e. an insulating layer 12. Note that the buried oxide layer 12 may itself be on a support substrate 2 which may again be formed of silicon or silicon-germanium, for example. Note that the support substrate 2 is not shown in the remaining Figures for clarity.

The silicon layer 10 can have a thickness of 8 nm or more, preferably 10 nm or more, to allow for the formation of the NiSi layer in a subsequent step.

A gate dielectric 14 for example of silicon dioxide or silicon nitride is formed on the silicon layer 10 and a metal-based gate 16 is formed. Those skilled in the art are familiar with deposition techniques for such layers and so these will not be described further.

The term “metal-based” includes metallic materials such as metal nitrides, metal silicide, metal alloys and/or multilayer structures, and the metal gate 16 may be for example of tungsten, tungsten silicide, tungsten nitride, titanium, platinum, molybdenum, molybdenum silicide or alloys or layers thereof. The layers may be implanted with various species as required. The term “metal-based” does not include polysilicon or amorphous silicon.

The gate 16 and gate dielectric 14 are then patterned. Although in the described embodiment, this patterning step is a single step, it is also possible to pattern gate and dielectric separately if required.

A spacer layer 20 is then deposited over the whole surface, including the silicon layer 10, the top of the gate 16, and the sidewalls of both gate 16 and gate dielectric 14. This leaves the structure shown in FIG. 1.

An anisotropic, vertical spacer etch is then carried out removing the spacer layer 20 from the top of the gate 16 and the top of the silicon layer, but leaving thin spacers 22 on the sidewalls of the gate 16 and gate dielectric 14. This step is carried out for sufficient time to not merely etch the spacer layer 20 but also to etch cavities 24 in the silicon layer 20 on either side of the gate 16, as illustrated in FIG. 2.

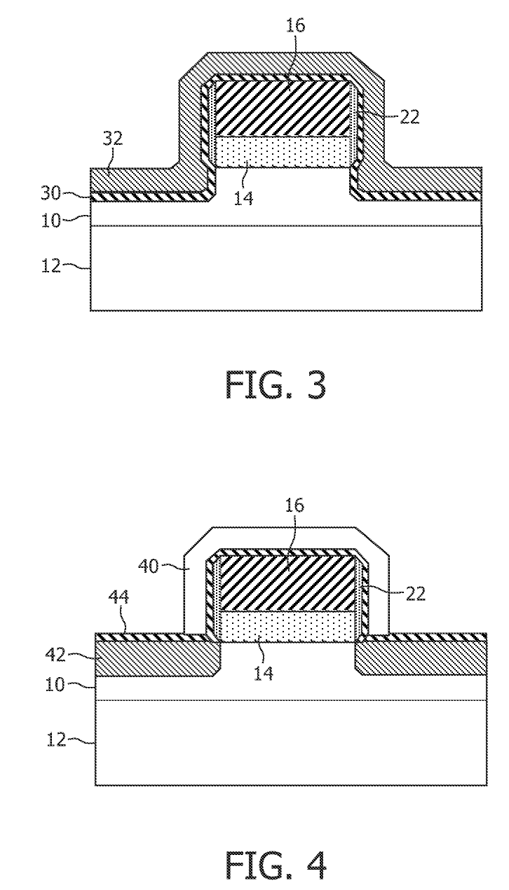

Referring to FIG. 3, a Ni layer 30 is then deposited over the whole surface, that is including the sidewalls and base of the cavities 24, the sidewalls of the spacers 22 and the top of the gate 16.

The Ni layer can be deposited by any convenient means, including sputtering, Metalorganic chemical vapour deposition (MOCVD), atomic layer deposition (ALD) or pulsed laser deposition (PLD). Sidewall coverage is not critical since the important thing is to deposit the Ni layer in cavities 24.

A doped amorphous silicon layer 32 is then deposited, again over the whole surface, filling the cavities 24 and covering the Ni layer 30 in the cavities 24, on the sidewall spacers 22 and on the top of the gate 16. This leads to the structure shown in FIG. 3.

The amorphous silicon layer can be deposited by any convenient means. As with the Ni layer, sidewall coverage is not critical since the important thing is to deposit the amorphous silicon layer at the base of cavities 24.

The doping of the amorphous silicon layer may be boron (B) to produce a p-type MOSFET (PMOS) or arsenic or phosphorous (P or As) to produce an n-type MOSFET (NMOS). The dopant may be introduced in any convenient way, for example by implantation or by forming the layer with the dopant.

An annealing step then follows at a temperature of 450° C. to 550° C.

In the regions where the amorphous silicon layer 32 is on a Ni layer 30 above the spacers 22 or gate 16, this annealing step simply regrows the amorphous silicon as polysilicon 40 over gate 16 and spacers 22.

However, in the regions where the Ni layer 30 is on the single crystal silicon of the silicon layer 10, the Ni reacts with the amorphous silicon 32 to form an NiSi layer 44. This layer then progresses through the amorphous silicon 32 from the single crystal silicon layer 10 upwards, the layer leaving doped monocrystalline silicon 42 behind it as it moves. The annealing is continued until the NiSi layer 44 reaches the upper surface of the doped amorphous silicon layer 32 in the cavities 24, as shown in FIG. 4.

A selective etch of polysilicon 40 is then carried out to remove the polysilicon 40 from the gate 16 and spacers 22, leaving the doped monocrystalline silicon 42 behind with a NiSi layer 44 on top.

The NiSi layer 44 is a contact layer that forms a good contact to the underlying doped monocrystalline silicon 42. The monocrystalline silicon 42 on either side of the gate forms source 50 and drain 52, and the silicon under the gate from the original silicon layer 10 forms the body 54.

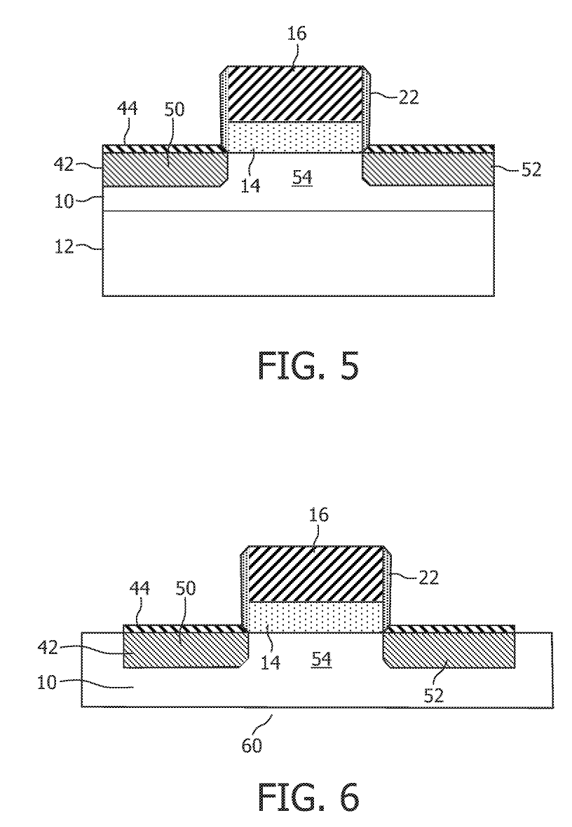

This results in the device shown in FIG. 5.

The device may then be finished by connecting to the gate 16, source 50 and drain 52.

The approach described allows the formation of the junction between the source 50 and body 54 and between the drain 52 and body 54 as well as the contacts 44 in a single step. The resulting junctions are highly activated, highly abrupt and very easy to position exactly.

The silicidation is extremely well controlled, which is unusual for silicidation steps on the thin silicon layers used in SOI processing.

Moreover, the approach is easy to integrate into advanced CMOS process flow.

Although the above embodiment is directed to a silicon on insulator device on an insulating substrate, the same invention can also be used with air as the insulating layer i.e. in a silicon on nothing (SON) device and the term silicon on insulator is intended to be interpreted as including such a SON device.

In an embodiment of this approach, part of the layer 12 is etched away leaving a cavity 60 under the transistor in the final device, as illustrated in FIG. 6. This step of etching away can occur either before or after the formation of the transistor as set out above. Note that if the transistor is formed first, the etching step chosen to etch away layer 12 will need to be chosen to avoid damage, for example to the silicide, but silicide is in fact fairly resistant to etching so this is entirely possible.

Note that the step of etching away the insulating layer need not take place as the final step, but could take place at an earlier stage.

Those skilled in the art will realise that the approach can be used to form either p-type or n-type transistors with a number of different forms. A number of transistors can be manufactured on a single substrate to form an integrated circuit.

1. A method of manufacturing a silicon on insulator semiconductor device, comprising:
providing a substrate with a silicon layer above a support layer;
forming a gate dielectric over the silicon layer, forming a gate over the gate dielectric and patterning the gate dielectric and gate;
depositing an insulating spacer layer over the top of the gate, the sidewalls of the gate and gate dielectric and the silicon layer adjacent to the gate;
carrying out a spacer etching step to etch the insulating spacer layer to form sidewall spacers on the sidewalls of the gate;
depositing a Ni layer over the silicon layer, over the gate and over the spacers;
forming doped amorphous silicon over the Ni layer over the and extending over the Ni layer on the gate;
annealing the device at a temperature of 450° C. to 550° C. to recrystallise the amorphous silicon from the Ni layer adjacent to the silicon layer as doped crystalline silicon and regrowing the amorphous silicon over the gate and spacers as polysilicon; and
selectively etching the polysilicon to remove the polysilicon from the spacers and gate leaving the doped crystalline silicon as source and drain.

2. A method according to claim 1 wherein the spacer etching step etches the silicon layer adjacent to the gate to form a cavity in the silicon layer; and
the step of forming doped amorphous silicone over the Ni layer fills the cavity.

3. A method according to claim 2 wherein the spacer etching step does not etch the full thickness of the silicon layer to form the cavity, thereby leaving silicon layer on the sidewalls and base of the cavity.

4. A method according to claim 1 wherein the annealing step leaves Ni silicide contacts over the doped crystalline silicon forming source and drain contacts to the source and drain of the doped crystalline silicone.

5. A method according to claim 1 wherein forming the doped amorphous silicon includes depositing the amorphous silicon over the surface of the nickel layer and then doping the amorphous silicon over the full surface of the amorphous silicon.

6. A method according to claim 1 wherein the support layer is an insulating layer that forms the insulating layer of the silicon on insulator structure.

7. A method according to claim 1 further comprising etching away the support layer under at least part of the silicon layer to generate a silicon on nothing structure.

8. A semiconductor device, comprising:
a crystalline silicon layer on a buried insulating layer;
a gate structure including a gate over a gate dielectric on the silicon layer and sidewall spacers on the sidewalls of the gate;
a source region and a drain region on opposed sides of the gate, wherein the source and drain regions are of highly doped crystalline silicon; and
a NiSi contact to both source and drain, wherein the NiSi contact extends to within 10 nm of the gate structure; and
the source region and drain region define an abrupt junction with the crystalline silicon layer.

9. A semiconductor device according to claim 8 wherein the abrupt junction of the source region and drain region with the silicon layer is a junction between doped regrown crystalline silicon of the source and drain regions and the crystalline silicon layer.
